(19) United States
(12) Patent Application Publication
(10) Pub. No.: US 2025/0198003 A1
(43) Pub. Date: Jun. 19, 2025

(54) SUBSTRATE PROCESSING APPARATUS AND SUBSTRATE PROCESSING METHOD

(71) Applicant: TES CO., LTD, Yongin-si (KR)

(72) Inventors: Kyung-Ho JANG, Yongin-si (KR); Min-Wook KANG, Yongin-si (KR); Byeong-Ho YUN, Yongin-si (KR); Jun-Ho HONG, Yongin-si (KR)

(73) Assignee: TES CO., LTD, Yongin-si (KR)

(21) Appl. No.: 18/983,106

(22) Filed: Dec. 16, 2024

(30) Foreign Application Priority Data
Dec. 18, 2023 (KR) 10-2023-0184828

(51) Int. Cl. C23C 16/458; C23C 16/44; C23C 16/455

(52) U.S. Cl. CPC C23C 16/4584; C23C 16/4412; C23C 16/45565

(57) ABSTRACT

A substrate processing apparatus includes a chamber, an upper showerhead, a lower showerhead, a liner, a substrate support ring, and a first driving unit. The chamber provides a processing space for a substrate, the upper showerhead is provided in an upper region of an interior of the chamber, and the lower showerhead is provided in a lower region of the interior of the chamber. The liner is provided in the interior of the chamber, and allows the substrate to be seated thereon. The substrate support ring allows the substrate to be seated thereon, and moves between the lower showerhead and the liner. The first driving unit raises, lowers, and rotates the lower showerhead, and tilts the lower showerhead with respect to the substrate.

### CROSS-REFERENCE TO RELATED APPLICATIONS

A claim for priority under 35 U.S.C. § 119 is made to Korean Patent Application No. 10-2023-0184828 filed on Dec. 18, 2023, in the Korean Intellectual Property Office, the entire contents of which are hereby incorporated by reference.

### BACKGROUND OF THE INVENTION

### Field of the Invention

The present invention relates to an apparatus and a method for processing a substrate, and more particularly to the apparatus and method both capable of adjusting a distance between a substrate and an upper showerhead or adjusting a distance between the substrate and a lower showerhead, and further capable of tilting the upper showerhead with respect to the substrate or tilting the lower showerhead with respect to the substrate.

### Description of the Related Art

In the prior art, a substrate processing apparatus deposits a thin film or a thin layer of a predetermined thickness on one side of a substrate, for example on a top surface of the substrate. In this case, when the thin films are deposited and superimposed on the top surface of the substrate, a stress of the thin films can cause the substrate to bow.

When the substrate is bowed in this manner, it becomes difficult to position the substrate in a correct position when the substrate is processed in various substrate processes that follow, and this bowing phenomenon reduces precision of the processes, especially while the precision of the substrate processes is increasing day by day. Therefore, to prevent the bowing phenomenon of the substrate described above, a thin film of a predetermined thickness is deposited on a bottom surface of the substrate.

Such a substrate processing apparatus is provided with an upper heater that supplies purge gas and the like to a top portion of the substrate, and a lower showerhead that supplies process gas to a bottom portion of the substrate.

Meanwhile, for a device that supplies the process gas toward the bottom surface of the substrate, such as the substrate processing apparatus described above, a distance between the substrate and the upper showerhead and a distance between the substrate and the lower showerhead are important. This is because when plasma is used during the process on the substrate, it is necessary to control a gap between the substrate and the upper showerhead so that the plasma does not generate between the substrate and the upper showerhead. In addition, a gap between the substrate and the lower showerhead is also important when the process gas is supplied toward the bottom surface of the substrate.

Moreover, due to various factors, the substrate and the upper showerhead may not be parallel and thus need to be aligned to be parallel. Further, the substrate and the lower showerhead may not be parallel and thus need to be aligned to be parallel. In contrast, it may be necessary to intentionally dispose the substrate and the upper showerhead in a non-parallel configuration and dispose the substrate and the lower showerhead in a non-parallel configuration, during the process on the substrate. In this case, it may be necessary to tilt the upper showerhead with respect to the substrate, or to tilt the lower showerhead with respect to the substrate.

### SUMMARY OF THE INVENTION

The present invention is contemplated to solve problems in the prior art mentioned above. Thus, it is an object of the present invention to provide a substrate processing apparatus and a substrate processing method, which are capable of adjusting a distance between a substrate and an upper showerhead or adjusting a distance between the substrate and a lower showerhead, and are further capable of tilting the upper showerhead with respect to substrate or tilting the lower showerhead with respect to the substrate.

To solve the above problems, according to a first aspect of the invention, the present invention may provide a substrate processing apparatus comprising: a chamber; an upper showerhead provided in an upper region of an interior of the chamber; a liner provided in the interior of the chamber and configured to allow a substrate to be supported thereon; a lower showerhead provided in a lower region of the interior of the chamber and configured to supply process gas toward a bottom surface of the substrate; a substrate support ring configured to allow the substrate to be seated thereon, and to move between the lower showerhead and the liner by a raising, a lowering or a rotation of the lower showerhead; and a first driving unit configured to raise, lower, and rotate the lower showerhead, and to tilt the lower showerhead with respect to the substrate.

Here, the substrate support ring may be formed with a plurality of protrusions, and the liner may be formed with through grooves through which the protrusions pass to be raised and lowered.

Further, the liner may be formed with a plurality of recesses in which the protrusions are seated.

Moreover, the liner may include at least one set of recesses which has the same number of the recesses as the number of the protrusions, and the liner may include a plurality of sets of recesses which have different heights, respectively.

Meanwhile, the liner may be formed with a step, and the though grooves and the recesses may be formed in the step.

Further, the liner may be formed with an exhaust hole through which gas inside the chamber is exhausted to the lower region of the interior of the chamber.

The first driving unit may include: a first elevation module configured to raise or lower the lower showerhead; a first tilting module configured to tilt the lower showerhead; and a rotation module configured to rotate the lower showerhead.

In this case, the first elevation module may include: a first elevation plate connected to a shaft of the lower showerhead; a first vertical connection bar to which the first elevation plate is connected to be raised and lowered; and a first elevation actuator configured to move the first elevation plate along the first vertical connection bar.

Further, the first tilting module may include: a first tilting plate connected to a shaft of the lower showerhead; and a first tilting actuator configured to tilt the first tilting plate.

One side of the first tilting plate may be connected to the first tilting actuator, and the other side of the first tilting plate may be tiltably connected to a first tilting connector which is connected to a lower surface of the chamber.

The other side of the first tilting plate may be connected to a first vertical connection bar, and a first elevation plate, which is connected to the shaft of the lower showerhead, may be connected to the first vertical connection bar.

In this case, the substrate processing apparatus may further comprise a first elevation plate connected to a shaft of the lower showerhead, wherein the rotation module configured to rotate the shaft of the lower showerhead with respect to the first elevation plate.

Meanwhile, the substrate processing apparatus may further comprise a second driving unit configured to raise and lower the upper showerhead, and to tilt the upper showerhead with respect to the substrate.

In this case, the second driving unit may include: a second elevation module configured to raise and lower the upper showerhead; and a second tilting module configured to tilt the upper showerhead.

Further, the second elevation module may include: a second elevation plate connected to a shaft of the upper showerhead; a second vertical connection bar to which the second elevation plate is connected to be raised and lowered; and a second elevation actuator configured to move the second elevation plate along the second vertical connection bar.

Further, the second tilting module may include: a second tilting plate connected to a shaft of the upper showerhead; and a second tilting actuator configured to tilt the second tilting plate.

One side of the second tilting plate may be connected to the second tilting actuator, and the other side of the second tilting plate may be tiltably connected to a second tilting connector which is connected to an upper surface of the chamber.

The other side of the first tilting plate may be connected to a second vertical connection bar, and a second elevation plate, which is connected to the shaft of the upper showerhead, may be connected to the second vertical connection bar.

Meanwhile, according to a second aspect of the invention, the present invention may provide a substrate processing method for a substrate processing apparatus, which includes a lower showerhead provided in a lower region of an interior of a chamber, a liner provided in the interior of the chamber and configured to allow the substrate to be seated thereon, and a substrate support ring configured to allow the substrate to be seated thereon, the method comprising: seating the substrate support ring on an upper surface of the lower showerhead by lowering the lower showerhead; seating the substrate on an upper surface of the substrate support ring; raising the lower showerhead to raise the substrate support ring above a height of the liner; and seating the substrate support ring on the liner by rotating and lowering the lower showerhead.

Here, the substrate support ring may be formed with a plurality of protrusions, and the liner may be formed with through grooves through which the protrusions pass to be raised and lowered. In this case, the raising of the lower showerhead may include raising the substrate support ring by passing the protrusions through the through grooves.

Further, the substrate support ring may be formed with a plurality of protrusions, and the liner may be formed with a plurality of recesses in which the protrusions are seated. In this case, the seating of the substrate support ring on the liner may include seating the protrusions of the substrate support ring in the recesses by rotating and lowering the lower showerhead.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIGS. 2A and 2B are perspective views each illustrating a liner and a substrate support ring of FIG. 1;

FIG. 3 is a side sectional view illustrating a lower showerhead raised by a first elevation module;

FIG. 4 is a perspective view illustrating the substrate support ring and the liner in a state as shown in FIG. 3;

FIG. 5 is a side sectional view illustrating the substrate support ring seated on the liner by rotating and lowering the lower showerhead;

FIG. 6 is a perspective view illustrating the substrate support ring and the liner in a state as shown in FIG. 5;

FIG. 7 is a side sectional view illustrating the lower showerhead tilted in one direction with respect to the substrate by a first tilting module;

FIG. 8 is a side sectional view illustrating a substrate processing apparatus according to another embodiment of the present invention;

FIG. 9 is a side sectional view illustrating both the upper and lower showerheads tilted while the substrate and the substrate support ring are seated on the liner;

FIG. 10 is a perspective view of a first tilting actuator of the substrate processing apparatus;

FIG. 11 is a sectional view taken along a line XI-XI of FIG. 10; and

FIG. 12 is a plan view of a first tilting plate.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to embodiments of the present invention will be described in detail with reference to accompanying drawings.

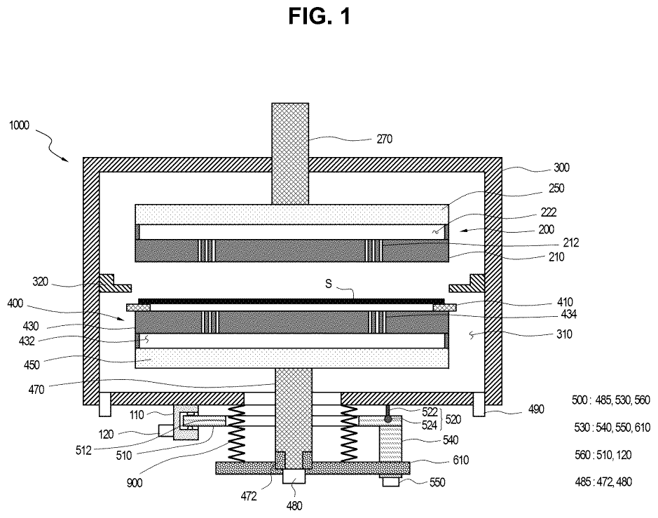

FIG. 1 is a side sectional view of a substrate processing apparatus 1000 according to one embodiment of the present invention.

Referring to FIG. 1, the substrate processing apparatus 1000 may include a chamber 300 providing a processing space 310 in which a process for a substrate S is performed, an upper showerhead 200 provided in an upper region of an interior or inside of the chamber 300, a lower showerhead 400 provided in a lower region of the interior or inside of the chamber 300 to supply process gas toward a bottom surface of the substrate S, a liner 320 which is provided in the interior or inside of the chamber 300 and on which the substrate S is rested or seated, and a substrate support ring 410 on which the substrate S is rested or seated and which is moved between the lower showerhead 400 and the liner 320 by a raising, a lowering, or a rotation of the lower showerhead 400.

Specifically, the chamber 300 may provide the processing space 310 in which various components necessary for the process on the substrate S are housed.

Any one side of the chamber 300 may be provided with an opening (not shown) through which the substrate S is loaded into the processing space 310 or unloaded from the processing space 310, and a door (not shown) may be provided to such an opening.

The upper region of the chamber 300 may be provided with the upper showerhead 200 for supplying the purge gas, such as inert gas, towards a top surface of the substrate S.

In addition, an upper part of the chamber 300 may be connected with a second shaft 270 through which the purge gas is supplied.

The purge gas supplied along the second shaft 270 may be fed downward through the upper showerhead 200.

The purge gas supplied at the upper showerhead 200 may be supplied toward the processing space 310 below and may prevent the process gas supplied from the lower showerhead 400 from entering the upper showerhead 200.

Specifically, the upper showerhead 200 may provide a first buffer space 222. Therefore, the purge gas supplied via the second shaft 270 may diffuse in the first buffer space 222 and may be supplied downward using first supply holes 212 through an upper shower head plate 210 of the upper showerhead 200. In FIG. 1, the first supply holes 212 are shown as being formed in only a portion of the upper showerhead plate 210 for illustrative convenience, but the first supply holes 212 may be formed across the entirety of the upper showerhead plate 220.

In addition, the upper region of the interior of the chamber 300 may be provided with an upper heater 250 for heating the substrate S. The upper heater 250 may be provided separately from the upper showerhead plate 210 as shown in FIG. 1, or may be integrated with the upper showerhead plate 210.

Meanwhile, the substrate processing apparatus 1000 may further include a Radio Frequency (RF) power supply (not shown) that applies RF power to at least one of the upper showerhead 200 and the lower showerhead 400.

For example, the upper showerhead 200 may be connected to the RF power supply (not shown) to be provided with the RF power. That is, the upper showerhead 200 may serve as an upper electrode. In this case, the lower showerhead 400 may be grounded to serve as a lower electrode.

When the RF power is applied to the upper showerhead 200 during the process on the substrate S, the upper showerhead 200 may be in capacitive coupling with the lower showerhead 400, and plasma may be generated between the upper showerhead 200 and the lower showerhead 430 to facilitate the process on the bottom surface of the substrate S.

Meanwhile, the interior of the chamber 300 may be provided with the liner 320 on which the substrate S is seated. The liner 320 may be provided along an inner wall of the chamber 300. Further, the substrate support ring 410 may support the substrate S, and may move between the liner 320 and the lower showerhead 400 by the raising, the lowering or the rotation of the lower showerhead 400 as described above. Hereinafter, the liner 320 and the substrate support ring 410 will be described in detail.

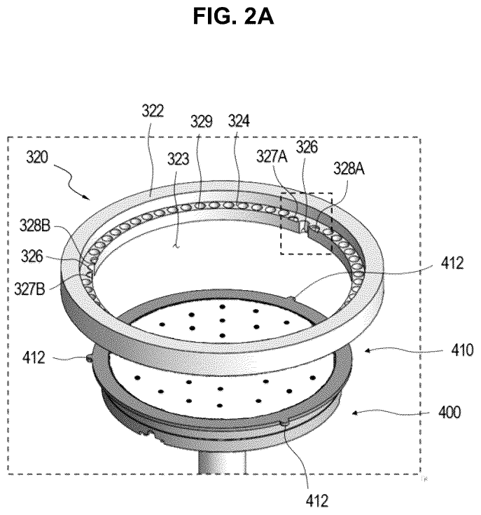

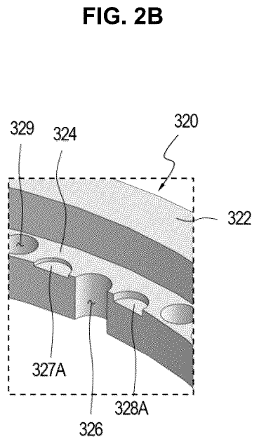

FIGS. 2A and 2B are drawings of the liner 320 and the substrate support ring 410 as described above. FIG. 2A is a perspective view of the liner 320 and the substrate support ring 410, and FIG. 2B is an enlarged view of an area indicated by a dashed line in FIG. 2A. FIGS. 2A and 2B illustrate a state in which the lower showerhead 400 is lowered. In FIGS. 2A and 2B, the substrate S is omitted for the sake of simplicity.

Referring to FIGS. 1, 2A, and 2B, the liner 320 may be provided along the inner wall of the chamber 300. In FIGS. 2A and 2B, the liner 320 is shown as a circular shape, but is not limited thereto.

An opening 323 may be formed at a center of the liner 320, and the substrate support ring 410 and an upper (or top) end part of the lower showerhead 400 may be raised and lowered by passing through the opening 323. To this end, an outer diameter of the substrate support ring 410 may be formed smaller than an inner diameter of the opening 323 of the liner 320.

On the other hand, a plurality of protrusions 412 may be formed on the substrate support ring 410. The protrusions 412 may be formed by extending radially, that is, outwardly, from the substrate supporter ring 410. The substrate support ring 410 may have the plurality of protrusions 412, which include three protrusions 412 as shown in FIGS. 2A, or may have two, four or more protrusions 412.

When the substrate support ring 410 is provided with the protrusion 412, a through groove 326 corresponding to the protrusion 412 may be formed at the liner 320. That is, the through groove 326 may be formed in the liner 320 such that the protrusion 412 does not interfere with the liner 320 when the substrate support ring 410 is raised or lowered. Thus, when the substrate support ring 410 is raised or lowered, the protrusion 412 may be raised and lowered by passing through the through groove 326 to prevent interference of the substrate support ring 410 with the liner 320.

Meanwhile, a plurality of recesses 327A, 328A, 327B, 328B may be formed on the liner 320 into which the protrusions 412 are seated or rested. That is, when the substrate support ring 410 is raised by passing through the liner 320, the protrusions 412 may be seated in the recesses 327A, 328A, 327B, 328B by rotating and lowering the lower showerhead 400 in order for the protrusions 412 to correspond to the recesses 327A, 328A, 327B, 328B. When the protrusions 412 are seated in the seating recesses 327A, 328A, 327B, 328B of the liner 320 and thus the substrate support ring 410 is supported by the liner 320, the lower showerhead 400 may then be lowered below the liner 320.

The recesses 327A, 328A, 327B, 328B may be formed in the liner 320, preferably to be adjacent to the through grooves 326 as described above. For example, as shown in FIGS. 2A and 2B, the recesses 327A, 328A, 327B, 328B may be formed right next to the through groove 326. Thereby, when the protrusions 412 are raised by passing through the through groove 326, an angle at which the lower showerhead 400 is rotated may be minimized in seating the protrusions 412 in the recesses 327A, 328A, 327B, 328B.

Meanwhile, the recesses 327A, 328A, 327B, 328B may be formed in respective sets each corresponding to the number of the protrusions 412 with different heights. That is, the recesses 327A, 328A, 327B, 328B may form a set of recesses 327A, 327B and a set of recesses 328A, 328B, each of which has the same number of the recesses as the number of the protrusions 412. There may be a plurality of sets of recesses 327A, 327B: 328A, 328B.

In this case, the sets of recesses 327A, 327B: 328A, 328B may comprise a first set of recesses 327A, 327B having a relatively smaller depth of recesses, and a second set of recesses 328A, 328B having a relatively greater depth of recesses. Such first set of recesses 327A, 327B and second set of recesses 328A, 328B may be formed in correspondence to the number of protrusions 412 along the through groove 326.

Further, it may be preferable that the first set of recesses 327A, 327B and the second set of recesses 328A, 328B are symmetrically disposed adjacent to the through groove 326, with respect to a central portion of the liner 320. Thereby, it may be ensured that when the protrusions 412 are seated on the liner 320, the protrusion 412 are seated in the first set of recesses 327A, 327B having the same depth of recesses or the second set of recesses 328A, 328B having the same depth of recesses.

As such, by varying the heights (or depths) of the recesses in the sets of recesses 327A, 327B: 328A, 328B, the distance between the top surface of the substrate S and the upper showerhead 200 may be adjusted. In other words, the distance between the substrate S and the upper showerhead 200 may be increased when the protrusions 412 of the substrate support ring 410 are rested in the second set of recesses 328A, 328B compared to when the protrusions 412 are rested in the first set of recesses 327A, 327B. Thus, by forming the sets of recesses 327A, 327B: 328A, 328B with different heights (or depths) of the recesses in the liner 320, the distance between the substrate S and the upper showerhead 200 may be adjustable.

Meanwhile, an exhaust hole 329 may be formed in the liner 320 for exhausting the gas located above the liner 320 to the lower region of the interior of the chamber 300.

When the substrate support ring 410 and the substrate S are seated on the upper (or top) part of the liner 320, the upper and lower regions of the chamber 300 may be separated or isolated with respect to the liner 320. Of course, such separation or isolation may not be a complete physical separation or isolation, but may interrupt gas flow between the upper and lower regions of the chamber 300.

Accordingly, the liner 320 may be provided with exhaust hole 329 to allow the gas inside the chamber 300 to be exhausted to the outside of the chamber 300 through an exhaust port 490 provided at a lower part of the chamber 300. The liner 320 may include a plurality of exhaust holes 329, and such exhaust holes 329 may be formed along the liner 320.

Meanwhile, a step 324 may be formed on the liner 320, and the through grooves 326, the recesses 327A, 328A, 327B, 328B, and the exhaust holes 329 as described above may be formed in the step 324.

Referring to FIG. 1, the lower showerhead 400 may serve to supply the process gas toward the bottom surface of the substrate S. In the present embodiment, the lower showerhead 400 may have the same configuration as the upper showerhead 200. That is, the lower showerhead 400 and the upper showerhead 200 may be manufactured to have the same configuration and may be interchangeable and compatible with each other.

For example, the lower showerhead 400 may provide a second buffer space 432. Therefore, the process gas supplied via a first shaft 470 may diffuse in the second buffer space 432 and may be supplied toward the bottom surface of the substrate S using second supply holes 434 through a lower shower head plate 430 of the lower showerhead 400. In FIG. 1, the second supply holes 434 are shown as being formed in only a portion of the lower showerhead plate 430 for illustrative convenience, but the second supply holes 434 may be formed across the entirety of the lower showerhead plate 430.

In addition, the lower showerhead 400 may be provided with a lower heater 450 for heating the substrate S. The lower heater 450 may be provided separately from the upper showerhead plate 430 as shown in FIG. 1, or may be integrated with the upper showerhead plate 430.

The first shaft 470 may extend downwardly from a lower part of the lower showerhead 400. When a lower end part of the first shaft 470 protrudes through the lower part of the chamber 300, a first bellows 900 may be provided to enclose the lower end part of the first shaft 470.

An upper end part of the first bellows 900 may be connected to a bottom (or lower) surface of the chamber 300, and a lower end part of the first bellows 900 may be connected to a first elevation plate 610, which will be described later.

Meanwhile, the process gas may be supplied to the lower showerhead 400 via a lower supply line (not shown) which passes through the first shaft 470. The lower showerhead 400 may be grounded to generate the plasma between the upper showerhead 200 and the lower showerhead 430 as described above.

Meanwhile, the purge gas supplied downwardly from the upper showerhead 200 may flow into the lower region of the chamber 300 and may be exhausted to the outside of the chamber 300 through the exhaust port 490.

Meanwhile, in a device that supplies the process gas toward the bottom surface of the substrate S, such as the substrate processing apparatus 1000 according to the present invention, a distance between the substrate S and the upper showerhead 200 and a distance between the substrate S and the lower showerhead 400 are important. This is because when the plasma is used during the process on the substrate S, it is necessary to control a gap between the substrate S and the upper showerhead 200 such that the plasma does not generate between the substrate S and the upper showerhead 200. In addition, a gap between the substrate S and the lower showerhead 430 also becomes important when the process gas is supplied toward the bottom surface of the substrate S.

Moreover, due to various factors, the substrate S and the lower showerhead 400 may not be arranged to be parallel and thus need to be aligned to be parallel. In contrast, it may be required to intentionally dispose the substrate S and the lower showerhead 400 not to be parallel, during the process on the substrate S. In this case, it may be required to tilt the lower showerhead 400 with respect to the substrate S.

For the tilting and the distance adjustment as described above, the substrate processing apparatus 1000 of the present invention may include a first driving unit 500 for raising, lowering, and rotating the lower showerhead 400, and for tilting the lower showerhead 400 with respect to the substrate S.

For example, the first driving unit 500 may include a first elevation module 530 for raising and lowering the lower showerhead 400, a first tilting module 560 for tilting the lower showerhead 400, and a rotation module 485 for rotating the lower showerhead 400.

The components provided at the chamber 300 will be discussed first, and then the driving unit 500, the first elevation module 530, the first tilting unit 560, and the rotation module 485 will be discussed.

In the following, left side (or end) portions of certain members or components in the drawings are referred to as a term “one side” and opposite right side (or end) portions thereof are referred to as a term “the other side” for better understanding of the configurations of the present invention. The term “one side” may be replaced by a term “a first side (or end)” and the term “the other side” may be replaced by a term “a second side (or end)”, and vice versa. Further, it should be appreciated that the positions of the members or components are not limited to the following descriptions, and such members or components could be arranged at any positions available under the concept and principle of operation of the present invention.

A first tilting housing 110 may be connected to the lower or bottom part of the chamber 300, and a first tilting plate 510 may be connected to the tilting housing 110 to be tiltable. In this case, a first tilting actuator 120 may be connected to the first tilting housing 110.

Specifically, one side of the first tilting plate 510 may be connected to the first tilting housing 110, and the other side of the first tilting plate 510 may be connected to a first tilting connector 520.

The first tilting connector 520 may include a first support bar 522 connected to the lower part of the chamber 300 and a first rotator 524 connected to an end of the support bar 522. The first rotator 524 may be formed in a spherical, semi-circular or curved shape such that the first rotator 524 may be rotatably or pivotably connected to the first tilting plate 510. Therefore, when one side of the first tilting plate 510 is moved up and down by the first tilting actuator 120, the entire first tilting plate 510 may be tilted by rotating or pivoting about the first tilting connector 520.

Further, an opening 512 may be formed at the first tilting plate 510, and the lower end part of the first shaft 470 may pass through the opening 512.

Meanwhile, the first vertical connection bar 540 may be disposed along a vertical direction and may be connected to a lower part of the other side of the first tilting plate 510. A first elevation plate 610 to which the first shaft 470 of the lower showerhead 400 is connected, may be connected to the first vertical connection bar 540, to be raised and lowered.

That is, the first elevation plate 610 may move up and down along the vertical connection bar 540. To this end, a linear motion (LM) actuator or guide (not shown) may be disposed inside the first vertical connection bar 540, and a first elevation actuator 550 may be connected to the first vertical connection bar 540. Accordingly, the LM actuator may be driven by the first elevation actuator 550 to cause the first elevation plate 610 to be raised and lowered along the first vertical connection bar 540.

Meanwhile, the lower showerhead 400 may be rotatably connected to the first elevation plate 610. For example, the first shaft 470 may be provided with the rotation module 485 for rotating the lower showerhead 400 relative to the first elevation plate 610.

The rotation module 485 may include a power source 480, such as a motor, and a power transmission 472 for rotating the first shaft 470 by driving or operating the power source 480. In this case, the power transmission 472 may comprise, for example, a magnetic fluid seal or the like.

Thus, the first shaft 470 may be rotated by driving the power source 480 and the power transmission 472.

Under the configuration as described above, an operation of the driving unit 500 will now be described.

Referring to FIGS. 1, 2A, and 2B, the first elevation module 530 may include the first elevation plate 610 connected to the first shaft 470 of the lower showerhead 400, the first vertical connection bar 540 to which the first elevation plate 610 is connected to be raised and lowered, and the first elevation actuator 550 for moving the first elevation plate 610 along the first vertical connection bar 540.

Further, the first vertical connection bar 540 may be connected to the other side of the first tilting plate 510 as described above, and the first tilting plate 510 may be connected to the lower part of the chamber 300 by the first tilting housing 110 and the first tilting connector 520.

Accordingly, the first elevation plate 610 may be raised and lowered along the first vertical connection bar 540 by the actuation or operation of the first elevation actuator 550, thereby raising and lowering the lower showerhead 400.

For example, as shown in FIGS. 1, 2A, and 2B, after the lower showerhead 400 is lowered and the substrate support ring 410 is seated on the upper (or top) surface of the lower showerhead 400, the substrate S may be seated on the upper (or top) surface of the substrate support ring 410. Subsequently, the lower showerhead 400 may be raised by the first elevation module 530 such that the substrate support ring 410 is raised above the height of the liner 320.

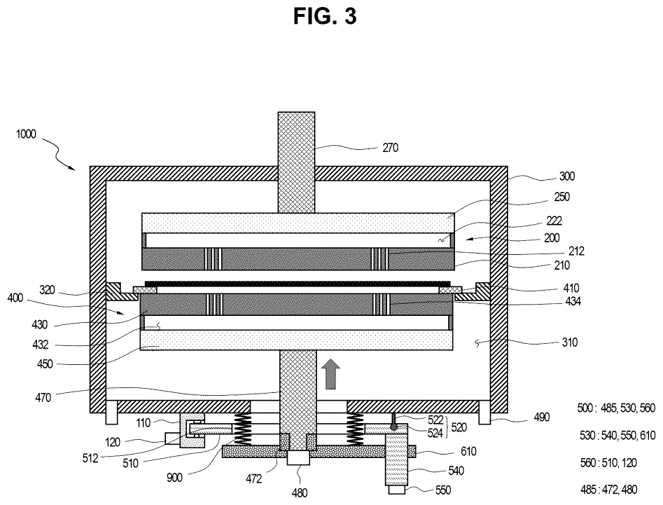

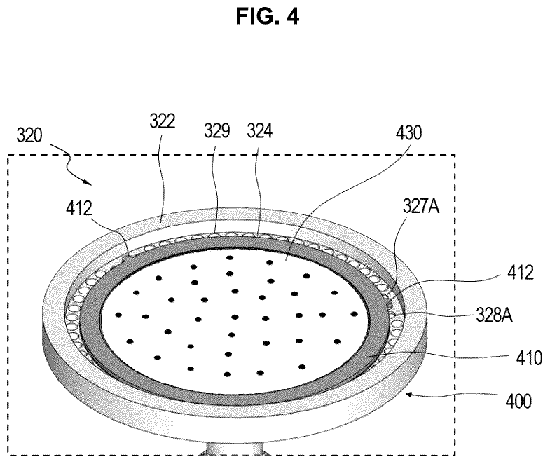

Meanwhile, FIG. 3 is a side sectional view illustrating a state in which the lower showerhead 400 is raised by the first elevation module 530, and FIG. 4 is a perspective view illustrating the substrate support ring 410 and liner 320 in the state of FIG. 3. In FIG. 4, the substrate S is omitted for simplicity of illustration.

As shown in FIG. 3 and FIG. 4, when the lower showerhead 400 is raised, the protrusions 412 of the substrate support ring 410 may penetrate or pass through the through groove 326 to cause the substrate support ring 410 to be raised above the liner 320.

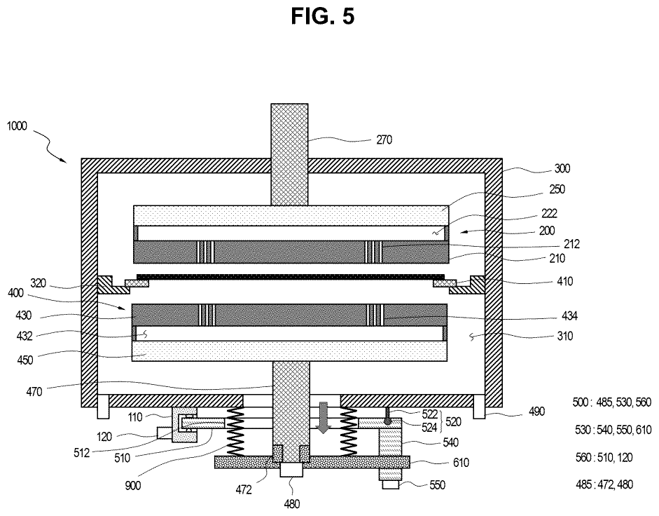

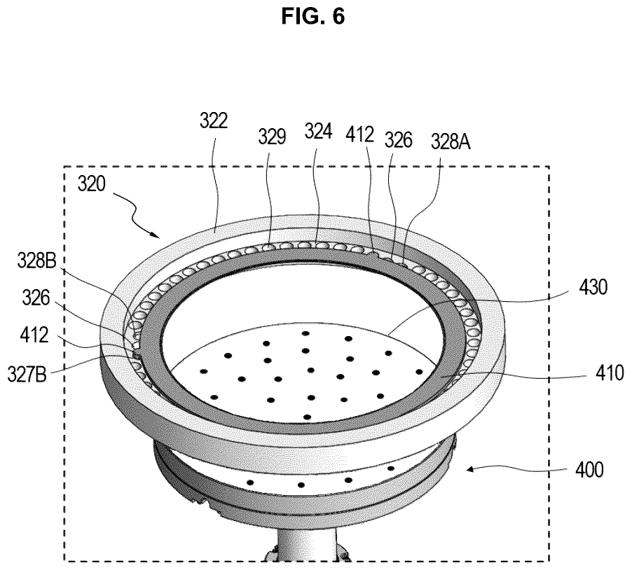

Meanwhile, FIG. 5 is a side sectional view illustrating a state in which the lower showerhead 400 is rotated and lowered so that the substrate support ring 410 is seated on the liner 320, and FIG. 6 is a perspective view illustrating the substrate support ring 410 and liner 320 in the state of FIG. 5. In FIG. 6, the substrate S is omitted for convenience of illustration.

As shown in FIGS. 5 and 6, when the substrate support ring 410 is seated on the liner 320, the lower showerhead 400 may be rotated in one direction and lowered from the state of FIG. 4 so that protrusions 412 of the substrate support ring 410 may be seated in the recesses 327A, 328A, 327B, 328B.

In this case, the lower showerhead 400 may be rotated by the rotation module 485 as described above. For example, the rotation module 485 may rotate the first shaft 470 with respect to the first elevation plate 610.

Thus, the first shaft 470 and the lower showerhead 400 may be rotated by operating the rotation module 485.

Meanwhile, the recesses 327A, 328A, 327B, 328B may have different depths as described above, and the gap between the top surface of the substrate S and the upper showerhead 200 may be adjusted according to the depths of the recesses 327A, 328A, 327B, 328B in which the protrusions 412 are seated.

Then, as shown in FIG. 5, the lower showerhead 400 may be lowered below the liner 320 by the first elevation module 530. In this case, the gap between the bottom surface of the substrate S and the lower showerhead 400 may be adjusted by adjusting the height of the lower showerhead 400.

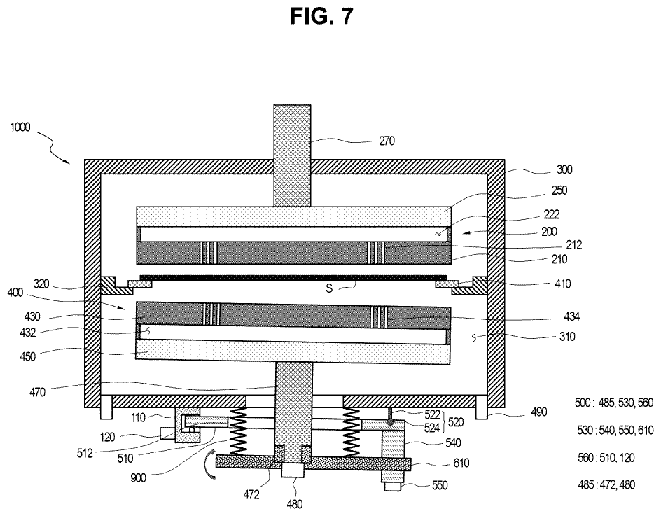

Meanwhile, FIG. 7 is a side sectional view illustrating a state in which the lower showerhead 400 is tilted in one direction with respect to the substrate S by the first tilting module 560 of the first driving unit 500.

Referring to FIG. 7, the lower showerhead 400 may be tilted by the first tilting module 560 while the first elevation plate 610 is fixed or secured to the first vertical connection bar 540 at a certain height.

For example, the first tilting module 560 may include the first tilting plate 510 connected to the first shaft 470 of the lower showerhead 400, and the first tilting actuator 120 for tilting the first tilting plate 510.

In this case, one side of the first tilting plate 510 may be connected to the first tilting actuator 120, and the other side of the first tilting plate 510 may be connected to be tiltable to the first tilting connector 520 which is connected to the lower (or bottom) surface of the chamber 300.

Further, the other side of the first tilting plate 510 may be connected to the first vertical connection bar 540, and the first elevation plate 610, which is connected to the first shaft 470 of the lower showerhead 400, may be connected to the first vertical connection bar 540.

Thus, when the first tilting plate 510 is tilted by operating the first tilting actuator 120 while the first elevation plate 610 is fixed to the first vertical connection bar 540 to maintain a certain height, the first vertical connection bar 540 and the first elevation plate 610 may be tilted together to tilt the lower showerhead 400.

Meanwhile, in the above embodiment, it is possible to tilt the lower showerhead 400 with respect to the substrate S, but it is difficult to tilt the upper showerhead 200 with respect to the substrate S. Also, in the above embodiment, it is possible to adjust the gap between the substrate S and the upper showerhead 200 by the recesses 327A, 328A, 327B, 328B of the liner 320, but it is difficult to adjust the upper showerhead 200 and the substrate S to have various gaps.

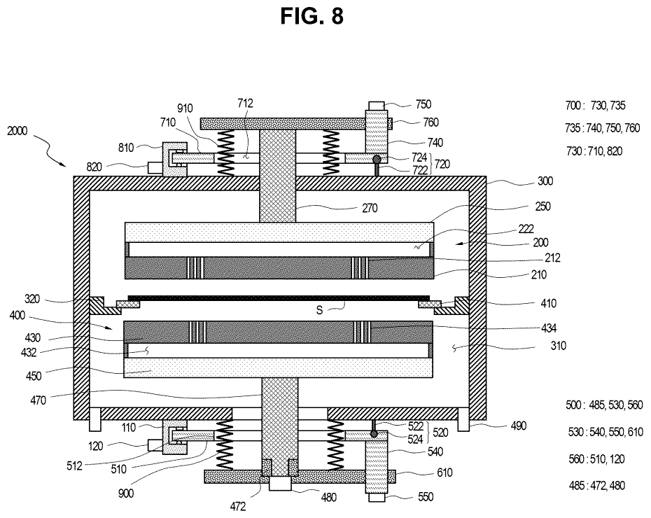

Meanwhile, FIG. 8 is a side sectional view illustrating a substrate processing apparatus 2000 according to another embodiment of the present invention for solving such problems. In FIG. 8, the same reference numerals are used for the same components compared to the above embodiment.

Referring to FIG. 8, the substrate processing apparatus 2000 may further include a second driving unit 700 for raising and lowering the upper showerhead 200, and for tilting the upper showerhead 200 with respect to the substrate S.

The second driving unit 700 may have a similar configuration compared to the first driving unit 500 described above, except for the configuration of the rotation module 485, and may be provided at the upper part of the chamber 300 and have a symmetrical structure to the first driving unit 500 described above. In this case, as described above, since the upper showerhead 200 and the lower showerhead 400 are configured to have the same structure, the second driving unit 700 may also have a similar configuration to the first driving unit 500.

For example, the second driving unit 700 may include a second elevation module 735 for raising and lowering the upper showerhead 200, and a second tilting module 730 for tilting the upper showerhead 200.

In this case, the second elevation module 735 may include a second elevation plate 760 connected to the second shaft 270 of the upper showerhead 200, a second vertical connection bar 740 to which the second elevation plate 760 is connected to be raised and lowered, and a second elevation actuator 750 for moving the second elevation plate 760 along the second vertical connection bar 740.

Further, the second tilting module 730 may include a second tilting plate 710 connected to the second shaft 270 of the upper showerhead 200, and the second tilting actuator 820 for tilting the second tilting plate 710.

In this case, one side of the second tilting plate 710 may be connected to the second tilting actuator 820 via a second tilting housing 810, and the other side of the second tilting plate 710 may be connected to be tiltable to a second tilting connector 720 which is connected to an upper (or top) surface of the chamber 300.

The second tilting connector 720 may include a second support bar 722 connected to the upper part of the chamber 300 and a second rotator 724 connected to an end of the second support bar 722. The second rotator 724 may be formed in a spherical, semi-circular or curved shape such that the second rotator 724 may be rotatably or pivotably connected to the second tilting plate 710.

Therefore, when one side of the second tilting plate 710 is moved up and down by the second tilting actuator 820, the entire second tilting plate 710 may be tilted by rotating or pivoting about the second tilting connector 720.

Meanwhile, the other side of the second tilting plate 710 may be connected to the second vertical connection bar 740, and the second elevation plate 710, which is connected to the second shaft 270 of the upper showerhead 200, may be connected to the second vertical connection bar 740.

Accordingly, the second elevation plate 760 may be raised and lowered along the second vertical connection bar 740 by the actuation or operation of the second elevation actuator 750 of the second elevation module 735, and thus may raise and lower the upper showerhead 200. Due to such a configuration, the gap between the upper showerhead 200 and the substrate S may be adjusted.

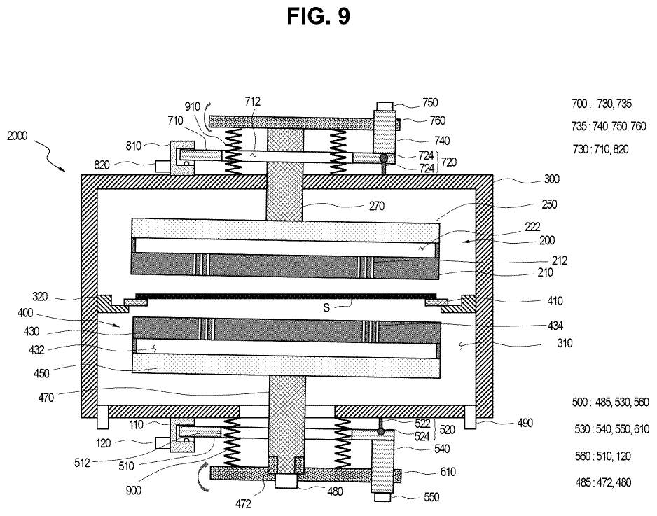

Meanwhile, FIG. 9 is a side sectional view illustrating a state in which both the upper showerhead 200 and lower showerhead 400 are tilted while the substrate S and the substrate support ring 410 are seated on the liner 320.

Referring now to FIG. 9, when the second tilting actuator 820 is driven to move one side of the second tilting plate 710 up and down while the second elevation plate 760 is secured to the second vertical connection bar 740, the entire second tilting plate 710 may be tilted by rotating about the second tilting connector 720.

In this case, the upper showerhead 200 connected to the second elevation plate 760 may also be tilted with respect to the substrate S.

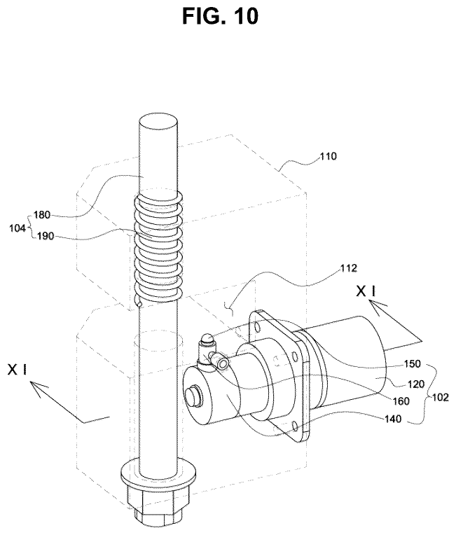

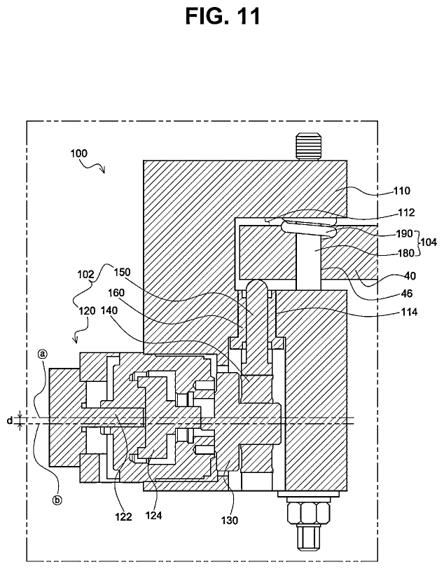

Meanwhile, FIGS. 10 and 11 correspond to drawings illustrating the operation of the first tilting actuator 120 as previously discussed.

FIG. 10 is a perspective view of the first tilting actuator 120 of the substrate processing apparatus 1000.

Referring to FIG. 10, the substrate processing apparatus 1000 may be provided with a first adjustment unit 102 for rotating the first tilting plate 510 up and down by a predetermined distance, and a second adjustment unit 104 for preventing the first tilting plate 510 from moving upward due to a negative pressure inside the chamber 300.

In other words, the first adjustment unit 102 may rotate one side of the first tilting plate 510 up and down in order to adjust a rotation angle of the first tilting plate 510.

The first adjustment unit 102 may be provided on the first tilting housing 110 which is connected to the lower part of the chamber 300, as shown in FIG. 10. The first tilting housing 110 may be fixed to the lower part of the chamber 300, and may be formed with a recess or groove 112 into which one side of the first tilting plate 510 is inserted. While being inserted into the recess 112, one side of the first tilting plate 510 may be slightly rotated up and down by the first adjustment unit 102, or the lifting of the first tilting plate 510 may be prevented and the height of the first tilting plate 510 may be secured or maintained by the second adjustment unit 104.

Meanwhile, the second adjustment unit 104 may include a spring member 190.

For example, the first tilting housing 110 may be provided with a fixing bar 180 that crosses the recess 112 in the vertical direction, and the spring member 190 may be provided on an upper part of the fixing bar 180. In this case, a through hole 46 through which the fixing bar 180 passes, may be formed in the first tilting plate 510, and the spring member 190 may press the first tilting plate 510 downwardly. The spring member 190 may be configured to prevent the first tilting plate 510 from moving upwardly when the negative pressure is generated inside the chamber 300 as described above. The above configuration is only an example, and it is of course possible to omit the configuration of the fixing bar 180, and to couple the spring member 190 directly to the first tilting housing 110 to press the first tilting plate 510, instead.

FIG. 11 is a cross-sectional view taken along a line XI-XI of FIG. 10.

Referring to FIG. 11, the first adjustment unit 102 may include a cam member 130 that applies a predetermined force to the first tilting plate 510, and the first tilting actuator 120 having a rotation shaft 122, which rotates the cam member 130 and is connected to the cam member 130 by being spaced from a center of rotation of the cam member 130 by a predetermined distance.

The first tilting actuator 120 such as a motor may be provided to the first tilting housing 110, and the rotation shaft 122 extending from the first tilting actuator 120 may be connected to the cam member 130. In this case, the center of rotation of the cam member 130 and the rotation shaft 122 of the first tilting actuator 120 may be connected by being spaced apart by a predetermined distance d. In FIG. 11, \textcircled{a} line corresponds to an imaginary or hypothetical line extending from a center of the rotation shaft 122 of the first tilting actuator 120, and \textcircled{b} line corresponds to an imaginary or hypothetical line extending from the center of rotation of the cam member 130.

That is, the rotation shaft 122 of the first tilting actuator 120 is not connected to the center of rotation of the cam member 130, but rather, the rotation shaft 122 of the first tilting actuator 120 may be connected to a position spaced apart by the predetermined distance from the center of rotation of the cam member 130. In such a configuration, when the rotation shaft 122 is rotated by driving the first tilting actuator 120, the cam member 130 may be also rotated together.

In this case, since the center of rotation of the cam member 130 is located to be spaced apart from the center of the rotation shaft 122, an outer circumference of the cam member 130 may have a varying distance from the rotation shaft 122 when the cam member 130 rotates. That is, when the cam member 130 rotates, the outer circumference of the cam member 130 may not form a constant circular trajectory, but may form an irregular trajectory in which the distance to the rotation shaft 122 varies. Therefore, when the distance between the outer circumference of the cam member 130 and the rotation shaft 122 becomes relatively long, the first tilting plate 510 may be rotated by being raised upwardly, and conversely, when the distance between the outer circumference of the cam member 130 and the rotation shaft 122 becomes relatively short, the first tilting plate 510 may be rotated by being lowered downwardly.

In this case, the substrate processing apparatus 1000 may further include a bearing element 140 provided between the cam member 130 and the first tilting plate 510 to enclose the outer circumference of the cam member 130 and exert the predetermined force on the first tilting plate 510. The bearing element 140 may prevent the cam member 130 from directly contacting a push bar 150 which will be described later, thereby preventing the wear of the cam member 130 or the push bar 150.

Moreover, the substrate processing apparatus 1000 may further include the push bar 150 whose one end contacts an outer circumference of the bearing element 140 to exert a predetermined force on the first tilting plate 510 by the rotation of the bearing element 140.

The push bar 150 may be disposed to be movable up and down through a linear bush 160 which passes through an opening 114 provided at the other side of the first tilting housing 110. When the push bar 150 is moved up and down by the rotation of the cam member 130, the linear bush 160 may guide the up and down movement of the push bar 150. Thus, when the bearing element 140 is rotated together by the rotation of the cam member 130, the push bar 150 may be moved up and down to cause the first tilting plate 510 to rotate by raising and lowering the tilting plate 510.

Further, the push bar 150 may support the first tilting plate 510 to prevent deflection or bending of the first tilting plate 510. That is, since the cam member 130 is engaged with and fixed on the rotation shaft 122 when the cam member 130 is not rotated, a height of an upper end part of the push bar 150 may be fixed or maintained to support the first tilting plate 510 and may prevent the deflection thereof.

Meanwhile, a reducer 124 may be positioned between the cam member 130 and the rotation shaft 122. The reducer 124 may decrease the rotational force of the rotation shaft 122 and transmit such rotational force to the cam member 130. In this case, a reduction ratio of the reducer 124 may be determined in correspondence to a maximum distance over which the tilting plate 510 can be raised and lowered.

The configuration of the second tilting actuator 820 in the substrate processing apparatus 2000 according to FIG. 8 is similar and symmetrical to the configuration of the first tilting actuator 120 as described above, and thus the further description for the second tilting actuator 820 is omitted.

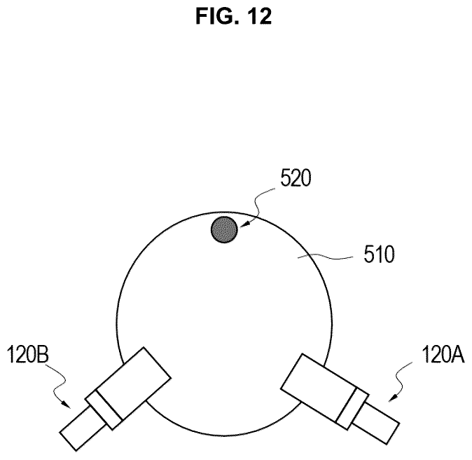

Meanwhile, FIG. 12 is a plan view of the first tilting plate 510, which illustrates the first tilting plate 510 and the first tilting actuators 120A, 120B.

As described above, in order to adjust the tilting angle and tilting direction of the first tilting plate 510, it may be preferable to provide a plurality of first tilting actuators 120A, 120B rather than the single first tilting actuator 120.

For example, as shown in FIG. 12, two first tilting actuators 120A, 120B may be provided to the first tilting plate 510. The number of the first tilting actuators 120A, 120B is described as an example, and it is also possible to provide more than two first actuators.

In this case, the first tilting plate 510 may be supported by the plurality of first tilting actuators 120A, 120B, or may be supported by the first tilting connector 520 and the plurality of first tilting actuators 120A, 120B. In the following, the first tilting plate 510 is assumed to have one first tilting connector 520 and two first tilting actuators 120A, 120B.

Here, the first tilting connector 520 may serve to support the first tilting plate 510 to be tilted, as described above.

When the first tilting plate 510 is provided with one first tilting connector 520 and two first tilting actuators 120A, 120B as shown in FIG. 12, the first tilting connector 520 and the first tilting actuators 120A, 120B may be symmetrically arranged. For example, the first tilting connector 520 and the first tilting actuators 120A, 120B may be disposed at a center angle of 120 degrees, respectively, with respect to the central portion of the first tilting plate 510.

In case of having such a plurality of first tilting actuators 120A, 120B, the tilting angles of the first tilting actuator 120A, 120B may be the same, or may be different from each other.

By making the tilting angles caused by the first tilting actuators 120A, 120B to be the same or different from each other, the tilting angle and the tilting direction of the first tilting plate 510 may be adjusted.

The substrate processing apparatus and method according to the present invention has the technical advantages as follows.

According to the present invention with the configuration as described above, the distance between the substrate and the upper showerhead or the distance between the substrate and the lower showerhead can be adjusted, and furthermore, the upper showerhead or the lower showerhead can be tilted with respect to the substrate.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber;
an upper showerhead provided in an upper region of an interior of the chamber;
a liner provided in the interior of the chamber and configured to allow a substrate to be supported thereon;
a lower showerhead provided in a lower region of the interior of the chamber and configured to supply process gas toward a bottom surface of the substrate;
a substrate support ring configured to allow the substrate to be seated thereon, and to move between the lower showerhead and the liner by a raising, a lowering or a rotation of the lower showerhead; and
a first driving unit configured to raise, lower, and rotate the lower showerhead, and to tilt the lower showerhead with respect to the substrate.

2. The substrate processing apparatus of claim 1, wherein the substrate support ring is formed with a plurality of protrusions, and
wherein the liner is formed with through grooves through which the protrusions pass to be raised and lowered.

3. The substrate processing apparatus of claim 2, wherein the liner is formed with a plurality of recesses in which the protrusions are seated.

4. The substrate processing apparatus of claim 3, wherein the liner includes at least one set of recesses which has the same number of the recesses as the number of the protrusions, and
wherein the liner includes a plurality of sets of recesses which have different heights, respectively.

5. The substrate processing apparatus of claim 1, wherein the liner is formed with an exhaust hole through which gas inside the chamber is exhausted to the lower region of the interior of the chamber.

6. The substrate processing apparatus of claim 1, wherein the first driving unit includes:
a first elevation module configured to raise or lower the lower showerhead;
a first tilting module configured to tilt the lower showerhead; and
a rotation module configured to rotate the lower showerhead.

7. The substrate processing apparatus of claim 6, wherein the first elevation module includes:
a first elevation plate connected to a shaft of the lower showerhead;
a first vertical connection bar to which the first elevation plate is connected to be raised and lowered; and
a first elevation actuator configured to move the first elevation plate along the first vertical connection bar.

8. The substrate processing apparatus of claim 6, wherein the first tilting module includes:
a first tilting plate connected to a shaft of the lower showerhead; and
a first tilting actuator configured to tilt the first tilting plate.

9. The substrate processing apparatus of claim 8, wherein one side of the first tilting plate is connected to the first tilting actuator, and the other side of the first tilting plate is tiltably connected to a first tilting connector which is connected to a lower surface of the chamber.

10. The substrate processing apparatus of claim 8, wherein the other side of the first tilting plate is connected to a first vertical connection bar, and
wherein a first elevation plate, which is connected to the shaft of the lower showerhead, is connected to the first vertical connection bar.

11. The substrate processing apparatus of claim 6, further comprising a first elevation plate connected to a shaft of the lower showerhead,
wherein the rotation module configured to rotate the shaft of the lower showerhead with respect to the first elevation plate.

12. The substrate processing apparatus of claim 1, further comprising a second driving unit configured to raise and lower the upper showerhead, and to tilt the upper showerhead with respect to the substrate.

13. The substrate processing apparatus of claim 12, wherein the second driving unit includes:
a second elevation module configured to raise and lower the upper showerhead; and
a second tilting module configured to tilt the upper showerhead.

14. The substrate processing apparatus of claim 13, wherein the second elevation module includes:
a second elevation plate connected to a shaft of the upper showerhead;
a second vertical connection bar to which the second elevation plate is connected to be raised and lowered; and
a second elevation actuator configured to move the second elevation plate along the second vertical connection bar.

15. The substrate processing apparatus of claim 13, wherein the second tilting module includes:
a second tilting plate connected to a shaft of the upper showerhead; and
a second tilting actuator configured to tilt the second tilting plate.

16. The substrate processing apparatus of claim 15, wherein one side of the second tilting plate is connected to the second tilting actuator, and the other side of the second tilting plate is tiltably connected to a second tilting connector which is connected to an upper surface of the chamber.

17. The substrate processing apparatus of claim 15, wherein the other side of the first tilting plate is connected to a second vertical connection bar, and
wherein a second elevation plate, which is connected to the shaft of the upper showerhead, is connected to the second vertical connection bar.

18. A substrate processing method for a substrate processing apparatus, which includes a lower showerhead provided in a lower region of an interior of a chamber, a liner provided in the interior of the chamber and configured to allow the substrate to be seated thereon, and a substrate support ring configured to allow the substrate to be seated thereon, the method comprising:
seating the substrate support ring on an upper surface of the lower showerhead by lowering the lower showerhead;
seating the substrate on an upper surface of the substrate support ring;
raising the lower showerhead to raise the substrate support ring above a height of the liner; and
seating the substrate support ring on the liner by rotating and lowering the lower showerhead.

19. The substrate processing method of claim 18, wherein the substrate support ring is formed with a plurality of protrusions, and the liner is formed with through grooves through which the protrusions pass to be raised and lowered, and
wherein the raising of the lower showerhead includes raising the substrate support ring by passing the protrusions through the through grooves.

20. The substrate processing method of claim 18, wherein the substrate support ring is formed with a plurality of protrusions, and the liner is formed with a plurality of recesses in which the protrusions are seated, and
wherein the seating of the substrate support ring on the liner includes seating the protrusions of the substrate support ring in the recesses by rotating and lowering the lower showerhead.
